(19) United States
(12) Patent Application Publication
(10) Pub. No.: US 2025/0338462 A1
(43) Pub. Date: Oct. 30, 2025

(54) SYSTEMS, DEVICES, AND METHODS FOR COOLING A DISPLAY

(71) Applicant: MEDIA RESOURCES INC., Oakville (CA)

(72) Inventors: Cheng Liang QIAN, Oakville (CA); Manu MOHAN, Oakville (CA); Yongbo TAN, Huizhou City (CN); Douglas Andrew PRICE, Dacula, GA (US)

(21) Appl. No.: 19/194,984

(22) Filed: Apr. 30, 2025

Related U.S. Application Data
(60) Provisional application No. 63/640,292, filed on Apr. 30, 2024.

(51) Int. Cl. H05K 7/20

(52) U.S. Cl. CPC H05K 7/20963

(57) ABSTRACT

Disclosed herein are systems, devices, and methods for a housing for a display, the housing comprising: at least one display connected to at least one heatsink plate, each heatsink plate connected to a door, each door closeable to connect the heatsink plate to a channel member of at least one channel member and openable to disconnect the heatsink plate from the channel member; each channel member defining a channel through housing, the channel sealed from an interior of housing and configured to receive gas from outside the housing and to exhaust gas to outside the housing; and the housing sealed from an atmosphere outside of the housing.

### CROSS-REFERENCE TO RELATED APPLICATION

This application claims priority to U.S. Provisional Application Ser. No. 63/640,292, filed Apr. 30, 2024, the entire disclosure of which is hereby incorporated by reference.

### FIELD

The present disclosure relates in general to the field of LED light displays and more particularly to an outdoor LED light display configured for heat dissipation.

### BACKGROUND

Prior art light-emitting diode (LED) light displays, direct view LED displays (dvLED) are flat panel displays that incorporate an array of light-emitting diodes to produce a display, for example, such as a visual display of information that may include text and/or graphics. The diodes function as pixels in the display. The brightness of an LED light display allows it to be used outdoors or indoors. LED light displays are commonly utilized as store signs, billboards, destination signs on public transport vehicles, and for other purposes of displaying information to an audience.

Generally, a dvLED display emits light from the entire view-facing side of the diodes, and the diodes generate heat. Management of the heat is crucial in order to permit stable and reliable performance as well as long operating lifetime. LED displays that are used in outdoor environments must withstand a variety of environmental factors, including weather events that may involve extreme heat, extreme cold, snow, rain, winds, and other weather events, as well as dust, car exhaust, dirt, moisture and other environmental effects that generally are generated outdoors. Moreover, LED displays intended for use in urban street-level environments must further withstand vandalism and mechanical impacts. For this type of LED display, herein referred as street level LED, the LED display will incorporate a housing or enclosure, such as a display cabinet structure with protective glass or transparent covers for the viewing faces and that is configured to prevent ingress of water. LED display cabinets require at least one wall to be formed of a transparent or virtually transparent materials, such as a glass to allow for visibility of the text and/or graphics generated by the LED Display, and such materials can be of a type that traps significant heat build-up within the cabinet.

Outdoor displays are typically exposed to varying environmental conditions, also including solar radiation, which presents a significant challenge in maintaining optimal operating temperatures. Solar radiation, particularly in regions with high ambient temperatures, can result in heat fluxes up to 1200 W/m², contributing to excessive heat buildup within the enclosed electronics of an outdoor display. This elevated temperature can compromise the performance and longevity of the internal components, and in extreme cases, may lead to thermal runaway.

The configuration of urban or street-level display has traditionally been configured with Liquid Crystal Display (LCD) flat panel technology with high brightness. LCD technology is not as power efficient as dvLED and requires substantial air cooling or air conditioning. The former solution of air cooling is simple and utilizes direct ambient air for cooling, but can permit dust accumulation in the interior of the display cabinet leading to performance degradation or damage to components. The latter solution of air conditioning requires more cost, space, complexity and power. Thus, an important drawback of existing LCD displays is the high cost of maintenance and ownership, both in terms of power consumption and frequency air filter changes to maintain cooling performance. There is a need for urban dvLED display that reduces or eliminates the need for air filters but can still effectively manage the temperatures.

The prior art includes many different methods and techniques to create a housing that is capable of dissipating the heat generated by displays, typically Liquid Crystal Display (LCD), or heat generated by discrete light emitting diodes.

Examples of prior art designed to address heat accumulation in an electronic display includes U.S. Pat. No. 9,797,588 for Expanded Heat Sink for Electronic Displays, issued to Manufacturing Resources International, Inc. on Oct. 24, 2017. This patent discloses an invention that positions one or more heat-generating components in thermal communication with a plate and utilizes one or more fans to draw cooling air along the plate to remove the heat from the component.

Another example of prior art is U.S. Pat. No. 9,542,870 for Billboard and lighting assembly with heat sink and three-part lens, issued to Ultravision Technologies, LLC on Jan. 10, 2017. This patent discloses a LED display that incorporates a heat sink that is thermally coupled to a surface of a substrate. The heat sink has a section substantially parallel to the substrate and a number of fins extending away from such section that are substantially perpendicular to such section. A longitudinal axis of each fin is substantially perpendicular to the longitudinal axis of the substrate. The LEDS are mounted in a manner whereby heat rises perpendicular to the surface of the fin. Some of the fins include a hole formed through the fin to enable heated air to rise through the fins and thereby generate heat dissipation in the LED display.

Yet another example is US Patent Application Publication No. 20090195159 (application Ser. No. 12/025,038) for LED cooling system, applied for by Jerry L. Smith on Feb. 3, 2008 (published on Aug. 6, 2009), which discloses an invention incorporating a LED chip, heat radiator, fan and self-containing power supply. The components are interconnected by spring loaded posts which absorb temperature expansion. A thermocouple device monitors the temperature and operates to shut off the LED chip before reaching a critical temperature.

Such prior art, which utilizes fans, components with holes therein to allow heat to rise, and a system that turns off the LEDs if they reach a certain temperature, are not sufficient to provide the heat dissipation and ease of maintenance that is required to support the continuous use of a LED display within a cabinet formed with a low cost of operation and extended operating lifetime.

Therefore, what is needed is a LED light display that provides high image quality (of clarity and visibility to a viewer of the LED light display) for the close distance viewing of urban or street-level application, that incorporates a cabinet that is created to withstand environmental effects and protect the LED display components positioned therein from such environmental effects, that can be utilized in a continuous manner, and that dissipates the heat generated without requiring air filter changes.

### SUMMARY

In accordance with an aspect, there is provided a housing for a display, the housing including at least one display connected to at least one heatsink plate, each heatsink plate connected to a door, each door closeable to connect the heatsink plate to a channel member of at least one channel member and openable to disconnect the heatsink plate from the channel member; each channel member defining a channel through housing, the channel sealed from an interior of housing and configured to receive gas from outside the housing and to exhaust gas to outside the housing; and the housing sealed from an atmosphere outside of the housing. In some embodiments, the gas is air.

In accordance with an aspect, there is provided a housing for a display, the housing including at least one display connected to at least one heatsink plate, each heatsink plate connected to a door, each door closeable to connect the heatsink plate to a channel member of at least one channel member and openable to disconnect the heatsink plate from the channel member; each channel member defining a channel through housing, the channel sealed from an interior of housing and configured to receive air from outside the housing and to exhaust air to outside the housing; and the housing sealed from an atmosphere outside of the housing.

In some embodiments, the door comprises at least one elongated member extending from the channel member to a door plate connectible to the heatsink plate.

In some embodiments, the housing includes at least one circulation device configured to circulate gas over a front surface of each display and behind each display.

In some embodiments, the at least one circulation device is a scroll fan.

In some embodiments, the housing includes at least one heat collector device positioned in a path of the circulated gas and connected to at least one channel member.

In some embodiments, the at least one heat collector device is an array of fins connecting through at least one heat pipe.

In some embodiments, the housing includes at least one axial fan configured to circulate the gas over the front surface of each display and behind each display.

In some embodiments, the housing includes at least one auxiliary inlet openable to unseal the housing from the atmosphere outside of the housing.

In some embodiments, the housing includes at least one processor configured to track a duration of time that the at least one auxiliary inlet opened and configured to generate an alert or data record based on the duration.

In some embodiments, the housing includes a frame fittable over at least one or more of the heatsink plate, the frames connectible to at least one other frame to form the door.

In some embodiments, frame includes at least one subhousing housing a control board and a power source for the display.

In some embodiments, frame includes at least one subhousing through which gas is received at a first corner from inside the housing and through which the gas is outputted at a second corner, the second corner diagonal from the first corner.

In some embodiments, the frame includes at least one subhousing comprising a set of pins or fins on an exterior surface of a metal cover, the inside of the metal cover contacting the control board through thermal interface material.

In some embodiments, the frame is rotatable.

In some embodiments, the housing further includes at least one infrared reflective layer in a glass extending over a front of at least one of the at least one display.

In some embodiments, at least one channel member comprises a surface treated, coated, painted, textured, or any combination thereof for heat transfer.

In some embodiments, at least one heatsink plate comprises a surface treated, coated, painted, textured, or any combination thereof for heat transfer.

In some embodiments, each heatsink plate is bonded to a printed circuit board with a thermal interface material positioned therebetween.

In accordance with an aspect, there is provided a method for cooling a display in a housing, the method comprising: circulating gas over a front surface of the display and then over a back surface of the display; thermally connecting the display, a component connected thereto, or both to a surface of at least one sealed channel through the housing; and moving external gas through the at least one sealed channel.

In some embodiments, the method includes receiving gas from outside the housing, moving the gas through the housing, and exhausting the gas to outside the housing.

In some embodiments, the method includes moving the gas in through a first corner of a subhousing in the housing, the subhousing housing a power supply, through the subhousing, and out through a second corner of the subhousing, the second corner diagonal from the first corner.

In some embodiments, the method includes providing radiative cooling to the display by absorbing heat from the display over a treated, coated, painted, textured, or any combination thereof surface of at least one sealed channel.

In some embodiments, the method includes providing radiative cooling to the display by absorbing heat from the display over a treated, coated, painted, textured, or any combination thereof surface of an interior face of a component of housing.

In some embodiments, the method includes reflecting infrared heat from reaching the front surface of the display.

In some embodiments, the method includes providing conductive heat transfer from the display or the component connected thereto to the at least one sealed channel.

In some embodiments, the method includes at least one reflector surface internal to the housing, the at least one reflector surface configured to redirect radiated heat rays toward the at least one sealed channel.

In this respect, before explaining at least one embodiment in detail, it is to be understood that the embodiments are not limited in its application to the details of construction and to the arrangements of the components set forth in the following description or illustrated in the drawings. Other embodiments are capable of being practiced and carried out in various ways. Also, it is to be understood that the phraseology and terminology employed herein are for the purpose of description and should not be regarded as limiting.

### BRIEF DESCRIPTION OF THE DRAWINGS

The invention will be better understood and objects of the invention will become apparent when consideration is given to the following detailed description thereof. Such description makes reference to the annexed drawings wherein:

FIG. 1 is a perspective view of a heatsink plate, in accordance with some embodiments;

FIG. 2 is an exploded view of LED display unit showing the heatsink plate, a printed circuit board assembly, and an thermal component, in accordance with some embodiments;

FIG. 3 is a perspective view of a heatsink plate and channel member, in accordance with some embodiments.

FIG. 4 is a perspective view of a LED display housing, in accordance with some embodiments;

FIG. 5. is a sectional view of a housing showing channel members therethrough, in accordance with some embodiments;

FIG. 6 is a perspective view of exterior components of a housing, in accordance with some embodiments;

FIG. 7 is a perspective view of a connection between heatsink plates and a channel member, in accordance with some embodiments;

FIG. 8 is a perspective view of heat collector with radiator fins in a housing, in accordance with some embodiments;

FIG. 9 is a perspective view of air flow through a core of a housing, in accordance with some embodiments;

FIG. 10 is a side sectional view of housing, in accordance with some embodiments;

FIG. 11 is a front view of a housing, in accordance with some embodiments;

FIG. 12 is a rear sectional view of a housing, in accordance with some embodiments;

FIG. 13 is a rear view of a frame with heatsink plates, in accordance with some embodiments;

FIG. 14 is a perspective view of a frame with heatsink plates, in accordance with some embodiments;

FIG. 15 is a rear view of airflow through adjacent frames fitted over heatsink plates, in accordance with some embodiments;

FIG. 16 is a perspective view of airflow through a frame fitted over heatsink plates, in accordance with some embodiments;

FIG. 17 is a perspective and side view of a lid component of a frame for heatsink plates, in accordance with some embodiments;

FIG. 18 is a top sectional view of a housing showing a channel member and heatsink plates, in accordance with some embodiments;

FIG. 19 is a top sectional perspective view of a housing showing a channel member and heatsink plates, in accordance with some embodiments;

FIG. 20 is a top sectional view of a housing showing a channel member and heatsink plates, in accordance with some embodiments;

FIG. 21 is a top sectional perspective view of a housing showing a channel member and heatsink plates, in accordance with some embodiments;

FIG. 22 is a perspective view of a channel member, in accordance with some embodiments;

FIG. 23 is a perspective view of a channel member, in accordance with some embodiments;

FIG. 24 is a perspective view of a channel member, in accordance with some embodiments;

FIG. 25 is a photograph of a rear view of an interior of a housing, in accordance with some embodiments;

FIG. 26 is a photograph of a heat unit including a frame and heat plates, in accordance with some embodiments;

FIG. 27A is a graph showing temperature over time for an unpainted and a painted subcabinet, in accordance with some embodiments;

FIG. 27B is a graph showing temperature over time for an unpainted and a painted internal component of a housing, in accordance with some embodiments; and

FIG. 27C is a graph showing temperature over time for an unpainted and a painted front of a heat unit, in accordance with some embodiments.

In the drawings, embodiments are illustrated by way of example. It is to be expressly understood that the description and drawings are only for the purpose of illustration and as an aid to understanding, and are not intended as a definition of the limits.

### DETAILED DESCRIPTION

In various embodiments, the orientation and/or directionality and/or relative positioning of components can be different than described, unless otherwise indicated. For example, references to “top” can be substituted with “bottom” in other embodiments; references to “bottom” can be substituted with “top” in other embodiments; references to “side” can be substituted with “top” or “bottom” in other embodiments; references to “left” can be substituted with “right” and “right” substituted with “left” in other embodiments; references to “front” can be substituted with “back” in other embodiments; references to “back” can be substituted with “front” in other embodiments. References to “fluid” may be substituted with “gas” in some embodiments. References to “fluid” may be substituted with “air” in some embodiments.

Described herein is a housing for a display that, in some embodiments, provides cooling to the display and related components. The display can be a LCD display or other type of display. The display can generate heat in operation. The display can be powered by a power source that generates heat.

Embodiments described herein can help address heat management via all three modes of heat transfer: conduction, convection and radiation, while maintaining environmental sealing of the display interior from weather, water, dust and without the need for routine filter changes.

In some embodiments, there is provided a LED display configured to incorporate: LED components formed from multiple LED diodes that collectively display text and/or graphics, said LED components being configured within or otherwise connected to a printed circuit board assembly (PCBA); a housing formed to withstand environmental effects having at least one glass wall whereby the LED components are visible to persons positioned facing the viewer-facing side of such LED component; and further having a heatsink plate forming an outer wall of the housing, said heatsink plate being positioned parallel or virtually parallel to the glass wall, said heatsink plate further incorporating ribs that form one or more heat sinks, and when the components are assembled, forming channel members. When assembled the heatsink plate is bonded to the PCBA via a bed of nails or mesa, configured to balance total contact pressure on the thermal interface material of the heatsink plate with the conduction performance, and one or more channel members are formed between the heatsink plate and the PCBA. As used herein, references to a housing can include a cabinet, in some embodiments. As used herein, references to a PCBA can be a printed circuit board assembly, in some embodiments.

Heat is drawn from the LED components and the PCBA into the heatsink plate, and the ribs in the heatsink plate draw such heat into heat sinks formed in the heatsink plate. From the heat sinks such heat is further directed into the channel members. Such channel members are formed such that the ends of the channel members meet holes formed in the housing, that are unblocked by the housing, such that the channel members are in open connection with the external environment. Heat travels through the channel members and is expelled into the environment external to the housing, thereby creating heat dissipation for the LED display.

Heat further can dissipate from the LED display if the external environment surrounding the housing is colder than the heat generated within the housing, because the heatsink plate forms an external wall of the housing. Some of the heat reaching the heatsink plate will dissipate due to heat exchange that occurs because the heatsink plate has direct contact with the colder external environment.

Embodiments leverage the skeleton of the heatsink plate to create cooling for the LED display. The skeleton can be formed as ribs, ridges or other extrusions from the side of the heatsink plate that is bonded to the PCBA (all such skeleton elements are referenced herein as “ribs” or “skeleton”). References herein to “skeleton”, “ribs”, or “skeleton elements” are to be understood as examples of projections, and other types of projections are to be understood as being able to be used in place of “skeleton”, “ribs”, or “skeleton elements” as the case may be, in other embodiments. Some of the ribs can form one or more heat sinks upon the face of the heatsink plate. Other ribs can form one or more channel members when the heatsink plate is bonded with the PCBA. The ribs can be formed to draw heat from the LED components to the heat sinks and to direct such heat into the one or more channel members. The heat travels through to channel members (which terminate with open access to the environment external to the housing), and the heat thereby travels outside of the housing.

The bonding of the heatsink plate and PCBA incorporates a means of positioning the heatsink plate and PCBA to be parallel or virtually parallel to each other at a distance from each other. The distance is created by bonding that incorporates nails, mesas, or some form of posts (all referenced herein as “nails”). The size and positioning of such nails are configured to cause the one or more channel members to form, and for the heat dissipation described herein to occur. In some embodiments such nails may form part of the skeleton or the ribs and have the same purpose and effect as the skeleton and ribs. The nails further balance the force between the heatsink plate and the PCBA.

When the LED display is assembled, the LED component generates heat and such heat flows to the PCBA and then to the heatsink plate. As described herein, there can be heat transfer from the heatsink plate to the external environment if the external environment is colder than the heat generated. The skeleton and ribs formed in the heatsink plate further are configured to draw such heat toward the central portion of one or more heat sinks formed in the heatsink plate. Such one or more central portions are positioned adjacent to one of the one or more channel members (and some channel members will be formed through the bonding of the PCBA and the heatsink plate). The heat that collects in the central portion of a heat sink is thereby drawn into the adjacent channel member. For example, as each channel member terminates with exposure to the external environment there can in some instances be an effect of temperature gradient (between inside and external environment) that draws the heat through the channel member towards the external environment and then out into the external environment. Other means of pushing heat into or drawing heat into a channel member may be incorporated in embodiments, such as fans. The effect is that heat is forced through a channel member and is thereby expelled into the external environment, which creates dissipation of heat generated within the housing.

In some embodiments, heat can be forced into one or more channel members due to the effect of a heat pipe assembly. A heat door operates as a coupler element between one or more channel members and a heat sink center, to draw heat from such heat sink center and into one or more channel members. A heat door can comprise a door plate (able to provide a connection between a heatsink plate and heat pipes) and heat pipes (able to provide a connection between the door plate and a channel member). Such heat door is formed to incorporate a heat coupling, which is operable to move the heat door between an open and a closed position. The heat coupling is configured such that it is operable to be utilized to open the heat door without the exertion of pressure on the front face of the heatsink plate (being the face of the heatsink plate having the ribs formed therein). The coupling door incorporates phase change heat pipes that may be formed of copper or other materials. The heat pipes are connected to a door plate component which is in contact with a portion of the heatsink plate (such as a heat sink portion of the heatsink plate) when the heat door is in a closed position.

The heat coupling is permanently attached to one or more heat pipes. When the heat door is closed a connection is created between one or more heat pipes and one or more channel members. Such connection causes heat to be drawn from the heatsink plate through the pipes and into one or more channel members.

The heat coupling incorporates a lever whereby it can be moved between the open and closed positions. In embodiments the heat door can further incorporate either or both of a spring-loaded component or one or more magnets, that pull the door plate into contact with the heatsink plate when the heat door is closed, or push the door plate to an opened position (whereby the door plate is not in contact with the heatsink plate, and the one or more pipes are not in contact with one or more channel members). In some embodiments one or more magnets could be used to pull the heat door to a closed position; and a spring-loaded component could pull the heat door to an opened position. Or in some embodiments solely a spring is used to pull the heat door to an open position and other springs act to push the heat door into a closed position of connection.

The air velocity through the pipes can be controlled by a push-pull configuration. If there are multiples pipes in an embodiment, if one or more pipes fail other pipes may still operate as described herein. Air velocity can further be achieved by one or more fans or blowers, or by other means operable to push and pull air through the pipes. Such fans, blowers or other means may be operable for redundant, adjustable fan speed. Air flow detection sensors may be incorporated in embodiments to sense and potentially monitor the air flow. Such sensors may deliver information collected by such sensors to a user of the LED display, and such information may further be utilized by digital technology linked to the LED display to control aspects of the operation of the LED display.

When the heat door is in a closed position the pipes are in contact with one or more channel members and the door plate of the heat door is in contact with a portion of the heatsink plate, such as heat sink formed in the heatsink plate, heat is drawn from the heatsink plate (such as from the central portion of a heat sink formed in the heatsink plate), into one or more pipes, through the one or more pipes and into one or more channel members. The heat then flow through the one or more channel members to the external environment, as disclosed herein, causing heat dissipation from the LED display. Each heat door is attached to at least one channel member.

Multiple heat doors may be incorporated within embodiments. The heat doors may be all opened or all closed, or various heat doors may be opened or closed at any point in time. The opening and closing of heat doors may be controlled by digital technology linked to the LED display or may be performed manually. The more heat doors that are closed generates an increased amount of heat being drawn into the channel members and thereby dissipated from the LED display. Therefore, the number of heat doors that are opened or closed may be determined by the temperature of the heat generated by the LED display at any period of the time, and the opening and closing of heat doors may be determined and controlled (such as by digital technology or manually) in accordance with such temperature. For example, more heat doors may be closed when the temperature of the heat generated by the LED display is higher and fewer heat doors may be closed when the temperature of the heat generated by the LED display is lower. One or more heat sensors may be incorporated in the LED display for the purpose of sensing the temperature of the heat generated within the LED display and within areas within the LED display. As described herein the temperature sensors may be linked to digital technology operable to control the opening and closing of heat doors.

As the channel members are open to the external environment it is possible that moisture or other environmental effects (including dust, snow, rain, or other environmental effects) may enter and flow inside the channel members. The housing of embodiments is formed to be sealed from environmental effects other than the channel members (which are open to the external environment). The interior of the housing is configured to allow water to flow through the channel members into the exterior of the housing. In some instances, if the water is colder than the heat generated by the LED display (such as water from a cold rain, or from snow or hail melt) such water may create a heat transfer that dissipates some of the heat within the LED display. Drains are formed in the housing to all for draining of water that enters the housing via the channel members from the housing, and thereby avoids any damage that could be created by build-up of water within the housing. Other environmental elements may also enter the channel members (e.g., dust, dirt, wind, etc.) and in the same manner as described for water herein, such elements could create heat transfer that assists with dissipation of heat from the LED display if the elements are colder than the heat generated by the LED display, and such elements could also drain or otherwise leave the housing through the drains formed in the housing.

Elements that are positioned such as they come into contact with any such environment elements are protected in embodiments, for example such as water protected fans.

In embodiments the wall of the PCBA that is bonded to the heatsink plate may be coated or otherwise protected such that a seal is formed within the housing between the heatsink plate interior wall and other elements within the housing, such that all environmental elements can solely come into contact with the heatsink plate and such coating or protective seal. Thus, as no environmental elements will reach any portion of the housing interior except the heatsink plate and the seal, no filtration is required to be incorporated in the LED display. The housing of embodiments of the present invention is configured such that the heatsink plate can be accessed and washed, or otherwise cleaned of any debris left, and any other defects caused by such environmental elements can be addressed. Due to the positioning of the channel members and drains in the housing, only minimal debris or effects of such environmental elements running through any channel members can reach the heatsink plate.

In accordance with some embodiments, many advantages can be provided. As an example, channel members create heat dissipation through the bonding of elements, and therefore do not require the incorporation of additional elements that prior art LED displays rely upon, and may not even incorporate such additional elements, within the housings for the purpose of heat dissipation (e.g., fans drawing cooling air, heat absorbing posts, etc.). The housing further incorporates the heatsink plate as an exterior wall which can also achieve heat dissipation, which prior art inventions wherein a heatsink plate is not an exterior wall, cannot not achieve.

As another example, in some embodiments, the heat doors generate a means of achieving controllable variable levels of heat dissipation for the LED display as a whole, and for areas within an LED display. Prior art LED display means of heat dissipation are not variable in this manner (e.g., fans that draw in cooling air, heat absorbing posts or holes cut into elements of the LED display, etc.).

As yet another example, in some embodiments, due to the configuration of the components, such components, other than the channel members and portions of the heatsink plate, are protected from any effect of the environmental elements, and such environmental elements can further be used to dissipate some heat from the LED display through natural heat exchange. Furthermore, the LED display can be formed to permit washing of the heatsink plate while the LED display remains on site where it is used to display text and graphics, and any debris or effects of such environment elements can be addresses on site. Other LED displays are susceptible to degradation from environmental elements or are entirely sealed from such elements which generates significant heat within such prior art LED displays.

Embodiments of housing may be formed of various materials, as are appropriate to the components of the LED display.

The discussion below provides information about some embodiments. A skilled reader will recognize that this discussion provides examples of possible embodiments, and that other embodiments are also possible.

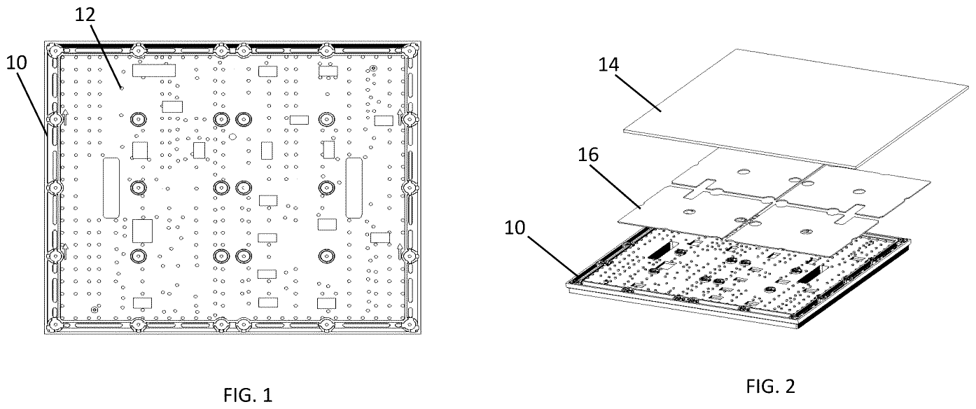

As shown in FIG. 1, the heatsink plate 10 incorporates one or more nails or mesa like standoffs 12 which position the heatsink plate 10 and PCBA 14 through a thermal interface material (TIM) 16 (as shown in FIG. 2), at a distance from each other when the heatsink plate 10 and PCBA 14 are bonded. The positioning of the nails 12 is configured to balance the force between the heatsink plate and the PCBA.

As shown in FIG. 4, in some embodiments, housing 26 incorporates the elements of a heatsink plate 10, PCBA 14 and display unit 260, and such components are aligned to be parallel or virtually parallel to each other when the LED display is assembled. These components are incorporated within a housing 26, as shown in FIG. 4 when the LED display is assembled. The heatsink plate 10 may form the back wall of the display 300, and the LED component may form the front wall of the housing, or in some embodiments a glass wall 29 may form the front wall of the housing. The housing further incorporates side walls 32, and, as shown in FIG. 4, a top wall 48 and a bottom wall 46.

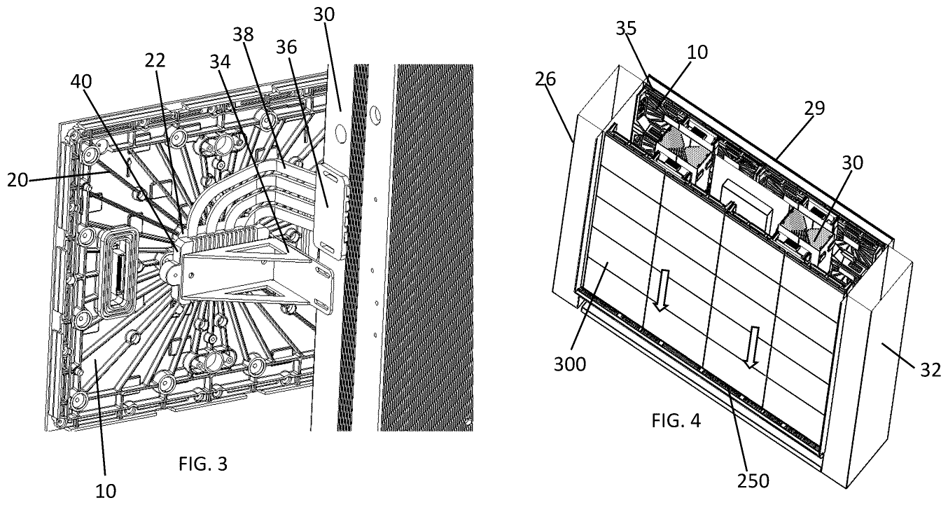

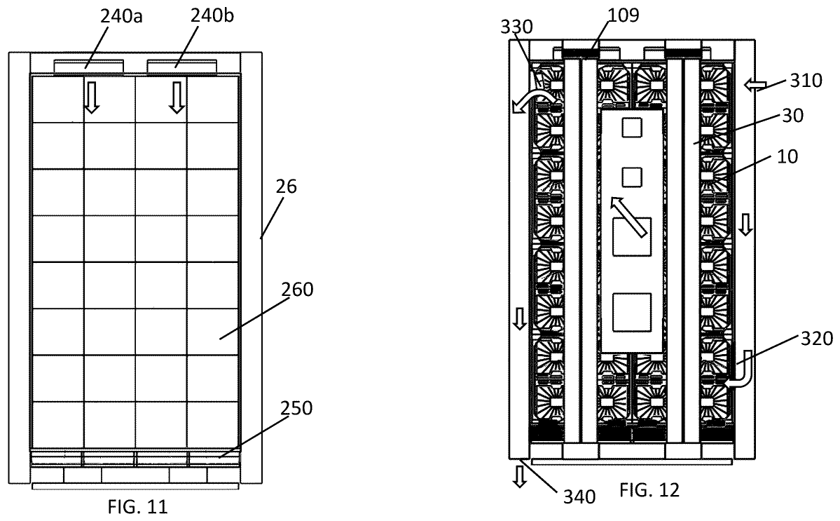

Either or both the heatsink plate 10 and the PCBA 14 may have a skeleton formed on the walls of each that face each other when the heatsink plate and PCBA are bonded. Such skeleton may form components that assist with heat dissipation and cooling of the LED display unit 260 (such as shown in FIG. 11). For example, as shown in FIG. 3, the heatsink plate incorporates one or more projections 20 that are configured to form a heat sink which draws heat into a heat sink center 22. Such skeleton may further form one or more channel members 30 which extend within the LED display and terminate in the upper wall of the housing and are not blocked at such termination, but are open to the environment outside of the LED display, as shown in FIGS. 4 to 6.

One or more heat pipe assembly 34 may be attached to one or more of the channel members 30, as shown in FIG. 3. A heat pipe assembly 34 may permit a removable connection between a heatsink plate and a channel member 30, for example. A heat pipe assembly 34 may be a single device in some embodiments and/or may not include a pipe formation in some embodiments. Each heat pipe assembly 34 may comprise a heat coupling 36, one or more heat pipes 38, and a door plate 40. The door plate may be in contact with heat sink center 22 in the heatsink plate 10, when the door is in a closed position. The heatsink plate may be positioned in contact with the heat sink center 22 integral with heat sink center 22. In some embodiments, where the display 300 which is designed to operate as a swingable door is closed, the pipes which is fixed at the channel member 30 by heat coupling 36 may further be in contact with heat sink plate 10 at the heat sink center 22. When the door is in a closed position the heat that is drawn to the heat sink center may be drawn into the pipes and flow through the pipes into the channel member, and flow through the channel member to the exterior of the LED display housing 26, to achieve heat dissipation for the LED display.

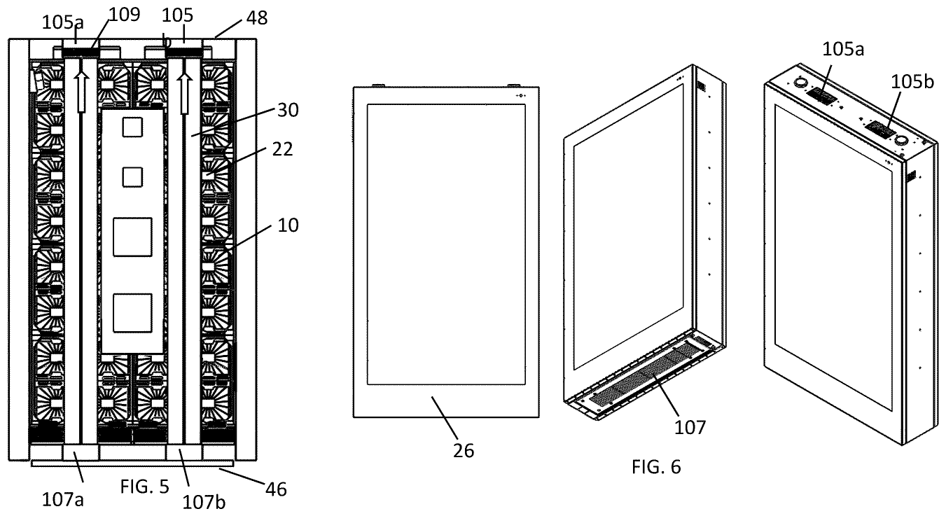

As shown in FIGS. 3 and 5 the one or more channel members may be positioned to extend through the LED display, and one or more heat pipe assembly 34 may be incorporated in the LED display positioned at various points along the one or more channel members. FIG. 22 shows an example channel member, according to some embodiments, with a textured or grooved surface to facilitate heat transfer, as well as drain elements 109. One or more drain elements (or fans) 109 may be positioned below or above the one or more channel members 30, and such drain elements may be open to the external environment to reject the heat from the LED display. The drain elements can be integrated into the bottom or top of the channel member 30 of the LED display as shown in FIGS. 5 and 22. The display housing is sealed and the channel member 30 is configured to dissipate heat dumped to the channel member 30 from various internal components to the external air.

In some embodiments, a housing 26 includes an arrangement of displays 300. For example, two displays 300a and 300b (FIG. 10) can be arranged with each back surface opposing each other.

### Sealed Housing

FIGS. 3, 4, 5, 6, and 7 show example housings 26 and internal components thereof, according to some embodiments. In some embodiments, housing 26 provides a sealed (or sealable, where openings such as side exhausts can be closed) enclosure, such sealed enclosure includes at least one display (e.g., LED display), heatsink plate(s) 10, and heat pipe(s) 38, the latter of which are connected to a channel member 30 that is opened or openable to the external environment and can receive and exhaust air (or other fluid) via the channel member 30 through opening(s) such as at a top and bottom of housing 26. Channel member 30 extends through housing 26 but is not in fluid communication with the sealed portion of housing 26. In other words, housing 26 provides a sealed (or sealable) enclosure from the environment outside housing 26 and further includes at least one channel member 30 that extends through housing from a first opening 107 (e.g., an intake) to a second opening 105 (e.g., an exhaust), where each opening is in fluid communication with the external environment. One of the openings can be at a top end of the channel member 30, while the other opening can be at a bottom end of channel member 30, for example.

### Channel Member(s)

In some embodiments, FIG. 6 shows an example housing 26 having at least one channel member 30 through housing 26, each channel member 30 having a first end being a first opening in housing and a second end being a second opening in housing 26. The openings can be outlet 105 (e.g., air exhaust) and inlet 107. In some embodiments, outlet 105 is positioned at the top of the housing 26 and inlet 107 is positioned at the bottom. In some embodiments, other configurations are possible. Each of outlet 105 and inlet 107 are fluid connectible with the external environment, for example, each can be directly in fluid communication with the external environment or, optionally, a device such as a fan or door or combination can be positioned to open and close or allow and restrict fluid flow into or out of outlet 105 or inlet 107. In some embodiments, housing 26 includes at least one channel member 30, each channel member receiving air (or other fluid) through an inlet 107 and exhausting at least a portion of the air through the outlet 105. Each outlet 105 and inlet 107 may be the terminus portions of a channel member 30 at opposite ends of housing 100, for example. Air (or other fluid) may be drawn via an intake 107, moved through channel member 30, and/or exhausted via outlet 105 using a fan 109 or other device (as shown by way of example in FIG. 5). In some embodiments, intake 107 and outlet 105 are each openings, each of which may both intake or exhaust air (or other fluid) and are not distinguishable from each other in that manner.

In accordance with some embodiments, FIG. 8 shows a cooling system for a LED display that includes a display in a housing 26, the housing 26 including at least one channel member 30 (e.g., two parallel channel members 30a and 30b extending from the top of the housing 26 (or towards the top) to the bottom of the housing 26 (or towards the bottom)), each channel member 30 capable of receiving air (or other fluid) from an exterior of the housing through an opening (e.g., inlet 107a or 107b). The air (or other fluid) is movable through the channel member 30 along the length of the housing 26. The air (or other fluid) from the exterior can provide a heatsink or heat exchanger capability, such as by receiving heat from inside the housing 26 (or becoming heated from heat received) and moving the heat (e.g., the heated air) through the channel member 30 away from the location that the heat is received. The housing 26 is sealed from external input, and air (or other fluid) is only received into each channel member(s) 30 through an intake(s) 107. In some embodiments, the housing 26 includes an emergency outlet (e.g., positioned at a side perimeter of housing) that is openable to facilitate cooling of housing 26, such as when a temperature detected in housing 26 exceeds a threshold temperature.

In some embodiments, an intake 107a is positioned at a first end of a first channel member 30a, the first end (e.g., top end) in fluid communication with outside the housing 26re at a first end (e.g., bottom) of the housing 26. Each channel member 30 is configured as such with its own intake (e.g., 105b), in some embodiments. The respective opening of each channel member 30 through which external air (or other fluid) is received may be at the same, opposite, or alternate ends of housing 100, in some embodiments. For example, in some embodiments, a first channel member 30a is positioned in the housing 26 and connecting a top end of the housing 26 to the bottom end of the housing 26, and a second channel member is spaced from the first channel member and parallel to the first channel member and connecting the top end of the housing to the bottom end of the housing. Each channel member 30 has an opening (e.g., at one of its ends) through which external air (or other fluid) is received or drawn in. Each channel member 30 has an opening at a different position (e.g., opposite end) through which the air (or other fluid) is exhausted.

In some embodiments, centrally, channel member(s) 30 act as a heatsink where ambient air is pulled through the respective channel (e.g., core) to remove heat from the system. In some embodiments, conduction, convection and radiation are used to transfer heat from all sources: display units 260, electronics (e.g., control board 412 and/or power source/supply 414), and solar load all to the channel member(s) 30 for removal. Channel member(s) 30 are formed such that the ends of the channel member(s) 30 meet openings (e.g., holes) formed in the housing 26, that are unblocked by the housing 26, such that the channel member(s) 30 are in open connection with the external environment. The exterior surfaces or faces of the channel member(s) 30 are within the weather protected interior of the LED display. Air is drawn through the channel defined by each channel member(s) 30 (e.g., core of plenum tubes) and removes heat by expulsion to the environment external to the housing 26, thereby creating heat dissipation for the display unit 260. Waterproof and dustproof sealed speed-controlled fans 109 are employed at the top and/or bottom of the channel member(s) 30 to create the air flow, in some embodiments.

A channel member 30 can be a plenum or tube for example. A display can be a LED display for example.

In some embodiments, the air velocity through the channel member(s) 30 can be created by a push-pull configuration of fans 109. Air velocity can be achieved by one or more fans or blowers, or by other devices or methods operable to push and pull air. Pairs of fans, blowers or other devices or methods may be operable for redundant, adjustable fan speed. In some embodiments one channel member(s) 30 may have two push fans and two pull fans. Air flow detection sensors may be incorporated in or at channel member(s) 30 to sense and potentially monitor the effectiveness of air flow and detect possible blockage of air or fan failures not noticeable through the fan's own fan speed sensor. Such air flow sensors and fan speed sensors may deliver data collected to be used to alert the user of the LED display of a need for servicing, and such data may further be used by one or more processors or circuit boards to control aspects of the operation of the LED display such as reduction of operating brightness. Such alerts can be transmitted to a user via a network using one or more processors or circuit boards operably connected to or included in housing 26.

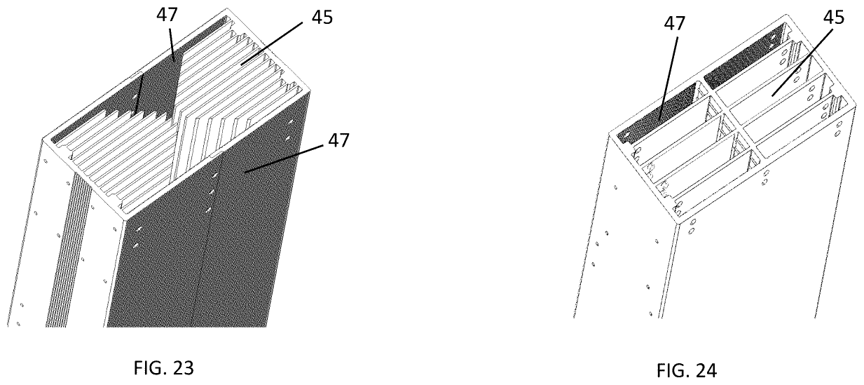

In some embodiments, at least a portion of an interior surface of a channel member(s) 30 is configured with interior shaped heatsink fins 45 and grooves 47 to increase surface area for efficient heat removal. The interior shaped heat sink fins 45 can be of different configuration selected based on its desired effectiveness as shown in FIGS. 23 and 24. The specific fan configuration can be selected based on a desired flow rate and pressure. The exterior walls or surfaces of the channel member(s) 30 are configured to maximize radiative, convective and conductive heat capture of the heat generated in the housing, in some embodiments. In some embodiments, the channel member(s) 30 are surface treated for maximum radiative absorption and surface area, the walls are ridged for increased surface area for convective and radiative heat transfer, and the conductive contact points are flat, unpainted and polished.

### Heatsink Plates

A display unit 260, in housing 26 can be coupled to heatsink plates 10 that can act as a heat sink to display 300. Heatsink plates 10 are arranged at a back surface of display unit 260, in some embodiments. FIG. 3 shows an example connection between a heatsink plate 10, and a channel member 30, according to some embodiments. In the embodiment shown, heatsink plate 10 includes projection 20 that extend away from a surface of heatsink plate 10, projection 20 can be a skeleton or ribs, for example. A portion of heatsink plate 10 abuts a door plate 40, such as at projection 20 or at a heat sink portion of heatsink plate 10 to which projection 20 extend from along a surface of heatsink plate. The connection between heatsink plate 10 and door plate 40 can be permanent in some embodiments or reversible in some embodiments where door plate is openable and closeable. Door plate 40 abuts (or is connected to or reversibly connectible to in various embodiments) at least one heat pipe(s) 38. At least one heat pipe(s) 38 extends from door plate 40 to at least one channel member 30. This configuration can allow heat to be drawn from heatsink plate 10 through heat pipes 38 and into one or more channel member(s) 30, according to some embodiments. In some embodiments, where used herein, references to “heat pipes” are to be understood as being elongated members and not necessarily pipes. In some embodiments, the connection between heatsink plate 10 and channel member 30 is arranged using a different thermal interface material (TIM) configuration that facilitates thermal coupling therebetween and allows channel member 30 to provide a heatsink or heat exchanger functionality. The connection can include a mesa style TIM interface on the diecast of the heatsink plate 10, for example.

FIG. 2 shows an exploded view of an example configuration of a display surface with PCBA 14, thermal interface material (TIM) 16 (e.g., thermal pad), and heatsink plate 10, which may also be referred to in some embodiments herein as heatsink plate 10.

In some embodiments, heat is drawn from the LED components (e.g., display 300) and a circuit board associated with the display 300 (e.g., PCBA) into a heatsink plate 10 associated with a display unit 260 (e.g., LED module), and projections extending from the heatsink plate 10 draw such heat into a transfer area formed in the heatsink plate 10. Some of the projections can form one or more heat sinks upon the face of the heatsink plate 10 or circuit board bonding face. These projections can increase the cross sectional area of conductive heat flow to the transfer area, improving the ability to maintain thermal uniformity on each display unit 260, according to some embodiments.

In some embodiments, the bonding of the heatsink plate 10 and circuit board (e.g., PCBA) incorporates a means of positioning the heatsink plate 10 and control board 412 to be parallel (or substantially parallel) to each other at a distance from each other. The distance is created by bonding that incorporates mesas or posts, in some embodiments. These posts are used to compress thermal interface material between the PCBA 14 and heatsink plate 10. The selection of post dimensions balances total thermal resistance from PCBA to heatsink plate versus total mechanical force. As thermal interface material requires compressive pressure to function, the selection of post quantity, height and contact area can accommodate high pressure but low total force in the module construction, improving the longevity of the assembly and protecting from material fatigue in thermal expansion and contraction.

In some embodiments, from the transfer area such heat is further transferred via conduction to the thermal interconnect bracket to the channel member(s) 30. The thermal interconnect bracket comprises formed supports and phase change heat pipes made of copper or other materials to efficiently conduct heat over the span to the channel member(s) 30. The thermal interconnect brackets are mechanically and permanently connected to the channel member(s) 30, but are separated from the display units 260 when the heat pipe assembly 34 are open for servicing. When the heat pipe assembly 34 are closed in normal operation, the thermal interface material between LED module heatsink plate 10 and thermal interconnect bracket is compressed, forming the conductive heat transfer interface. In some embodiments, the thermal interconnect bracket incorporates magnet features between the bracket and heatsink plate 10 to actively increase the contact force by pulling the two elements together when the heat pipe assembly 34 is in the closed position. In some embodiments this contact force feature may be of the form of a spring-loaded element, latch bar or cam that is manually or electromechanically operated by digital technology control. A mechanical support element on the thermal interconnect bracket stabilizes the assembly to prevent deflection when the heat pipe assembly 34 is closed.

Heat originating from the display units 260 or solar gain absorbed by the display units 260 use this conductive path to transfer into the plenum tubes for removal, in some embodiments.

### Air Circulation in Housing

In some embodiments, convective heat transfer is enhanced or provided by internal recirculation of air that seeks to efficiently transfer heat from higher temperature elements into the relatively cooler channel member(s) 30 which act as a heat sink. This internal recirculation maintains the environmental seal of the total housing 26 and does not require intake of external air, and therefore does not require filter maintenance, according to some embodiments. Further, the internal recirculation can help address the environmental solar heat gain which can otherwise multiply (e.g., double or more) the heat generated by display units 260. In some embodiments, one or several assemblies of scroll fans, axial fans or blowers are used to push and/or pull air in the form of a thin air curtain between the display face 300 and a protective glass 29 at the perimeter of housing 26 or covering display 300. In some embodiments, gases other than air can be circulated in housing 26, to enhance the heat transfer.

When solar gain acts on the housing 26, the heat is primarily absorbed at the surface of the display 300 face, and the air curtain can help remove the heat before it is soaked into the other components of the housing 26 such as display 300. In some embodiments, the heated air from at the display 300 face is pushed down from top-mounted scroll fans 240 and re-enters the internal space behind the display 300 to travel upwards, completing the air circuit.

FIG. 11 shows a front view of example air (or other fluid) movement through housing 26, according to some embodiments. In some embodiments, and as shown in FIG. 11, housing 26 includes at least one circulation device 240, such as scroll fan 240 positioned and configured to facilitate movement of air (or other fluid) through housing 26. This can advantageously provide thermal cooling to a display in housing 26. In FIG. 10, the display is depicted by display units 260 and heatsink plates 10 (not shown in FIG. 11) are positioned behind display units 260 such as bonded to circuit board(s) which are, in turn, connected to display unit(s) 260.

A circulation device 240, such as a scroll fan 240, is positioned in a sealed (or sealable, where openings such as side exhausts can be closed) portion of housing 26, such sealed portion includes at least one display, heatsink plates 10, and heat pipes 38, which are connected to a channel member 30 that is opened or openable to the external environment and can receive and exhaust air (or other fluid) via the channel member through opening(s) such as at a top and bottom of housing 26. Channel member 30 extends through housing 26 but is not in fluid communication with the sealed portion of housing 26. In other words, housing 26 provides a sealed (or sealable) enclosure from the environment outside housing 26 and further includes at least one channel member 30 that extends through housing from a first opening (e.g., an intake) to a second opening (e.g., an exhaust), where each opening is in fluid communication with the external environment. One of the openings can be at a top end of the channel member 30, while the other opening can be at a bottom end of channel member 30, for example.

In some embodiments, air (or other fluid) is moved or circulated in the sealed portion of housing 26. This can advantageously provide thermal cooling to the components in housing 26, including the display. FIG. 10, shows an example path of movement of air (or other fluid) within the sealed portion of housing 26. For example, in some embodiments, air is moved in housing 26 downwards in front of the display and circulated back upwards in housing 26 behind the display, such as behind heatsink plate(s) 10. In some embodiments, at least one scroll fan is positioned near a top perimeter in the sealed portion of housing 26 and are configured to generate a loop circulation of air (or other fluid) in housing 26, creating an air curtain in an interior front surface of housing 26 (e.g., in front of the display in housing 26). Upon reaching the bottom of the interior of housing 26, the air is forced to return upwards and behind heatsink plate(s) 10 as housing 26 is sealed to the external environment outside housing 26.

In some embodiments, air (or other fluid) is moved over the front of more than one display and circulated over more than one surfaces of heatsink plate(s) 10 associated with more than one display. For example, in the embodiment shown in FIG. 10 air is moved by a scroll fan 240a downwards over the surface of a first display 300a and upwards behind the back surface of the first display 300a, specifically, over the set of heatsink plate(s) 10 associated with the length of display 300a. This air stream moving upwards is joined by an analogous air stream moving upwards after having moved downwards over the surface of a second display 300b. The air stream moves upwards behind the back surface of the second display 300a, specifically, over the set of heatsink plate(s) 10 associated with the length of display 300b.

In some embodiments, other device(s) can be used in place of a scroll fan 240. In some embodiments, the air (or other fluid) circulated in housing 26 travels in a different path or orientation than as described, for example, the air (or other fluid) may travel upwards in front of the display and downwards behind the heatsink plate(s) 10, and/or scroll fan(s) 240 may be positioned at a bottom perimeter (or other location) inside housing 26 to facilitate the desired path of movement of air (or other fluid), for example.

In some embodiments, housing 26 includes at least one heat collector device 250 that meets the flow of the air (or other fluid). The heat collector device(s) 250 may be located when the air (or other fluid) reaches the location in housing 26 around where it changes direction (e.g., at a bottom of housing where air is forced to move behind heatsink plate(s) 10), such as shown in FIGS. 8, 9 and 11.

FIG. 8 shows an example configuration of a heat collector device 250 with radiator fins 255 through which the flow of air (or other fluid) moves near or at where it changes direction (e.g., at the bottom of housing 26). The direction of the flow of air is denoted by the solid arrows in FIG. 8. Heat collector device 250 is connected to at least one radiator heat pipe 270, which is also connected to channel member 30. Heat collector device 250 and its associated components (e.g., radiator fins 255 and radiator pipe(s) 270) can advantageously facilitate thermal cooling, according to some embodiments. For example, the air (or other fluid) moving in the housing 26 transfers heat to the radiator fins 255 as it passes between the radiator fins 255 and heat is transferred from the radiator fins 255 to channel member 30 via radiator heat pipe(s) 270. In some embodiments, a different configuration for transferring heat from heat collector device 250 to channel member 30 is used.

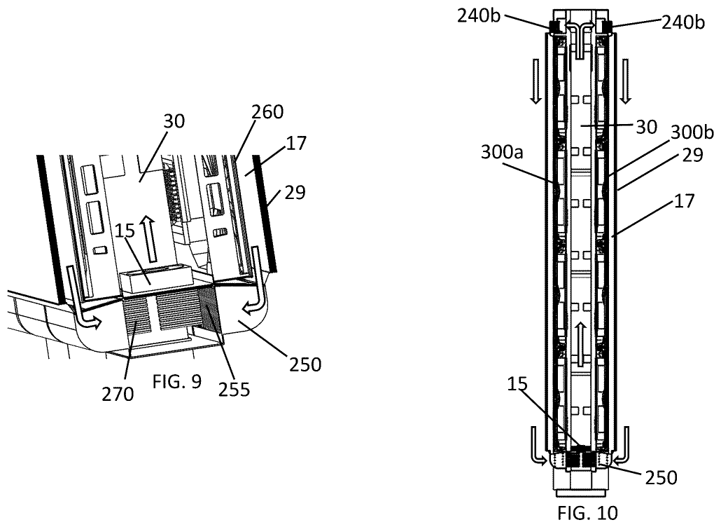

In some embodiments, housing 26 includes one or more fans (or other air or fluid moving devices) near heat collector device(s) 250 to support or increase the flow of air moving through housing 26, such as by mitigating friction and/or drag in the air flowing in housing 26 that heat collector device 250, where included, may contribute to. As examples, the types of devices that can be used can be scroll fans, axial fans, change radiators, or other devices. These devices can be used to balance pressure loss with heat transfer. As another example, heat collector device(s) 250 can include a fan or other air movement device to enhance air circulation and heat removal. These fans can support the movement of air provided by scroll fan(s) 240 in some embodiments (e.g. 15 in FIGS. 9 and 10). In some embodiments, instead of heat collector device(s) 250, other heat exchangers or connectors can be used.

FIG. 4 shows an example heat collector device 250 installed at a housing 26, according to some embodiments. The direction of the flow of air is denoted by the solid arrow in FIG. 4. Heat collector device 250 can be installed in the rearward direction below display 300 for example. The position of heat collector device(s) 250 can be selected based on a desired effect on air (or other fluid) flow in housing 26.

In some embodiments, cooling is provided through an internal circulation within the display core (inside housing 26, behind opposing displays 300, for example) and transfers the heat into a channel member 30 through a heat exchanger such as a heat collector device 250.

Scroll fan(s) 240 (or other air (or fluid) movement device) provide an air curtain on a front face inside housing 26 facilitating the removal of heat from heatsink plate(s) 10, associated/connected components, and/or heat generated from solar radiation such as received through a front panel (e.g., glass that covers a front surface of display 300) of housing 26.

A heat collector device 250 (or other heat exchanger) located below the display 300 or heatsink plate(s) 10 absorbs heat from the air curtain and transfers heat to channel member 30 through multiple heat pipes 270, according to some embodiments.

In some embodiments, one or more heat collector devices 250 are positioned within the path of the air circuit and connected thermally by phase change heat pipes to the channel member(s) 30. Heat collector devices can include radiators, for example. In some embodiments, the heat collector devices 250 are configured with radiator-type fins and heat pipes and collect heat from the passing air to transfer into the cooler channel member(s) 30. In some embodiments, the heat collector device(s) 250 are positioned at the bottom of the display 300 and receives the air at the highest temperature immediately after the air passes the heated display unit 260 surface. In some embodiments, the heat collector device(s) 250 dumps the heat to the coldest part of the channel member 30 which is at the bottom. Additional riser fan 15 assembles positioned behind the displays 300 can be used to increase air flow and pressure to offset pressure losses. Alternative arrangement and direction of air flow and heat collector 250 placement are also possible, for example with the fans and heat collectors positioned in series above or below the display 300, or with the fans pushing an upward air curtain and heat collector positioned above the display 300. The permutations of configurations, arrangements, and selection of heat collector and fan assemblies are not restricted or limited to that described herein.

### Auxiliary Inlet

In some embodiments, housing 26 includes an auxiliary inlet through which air (or other fluid) can be received into the otherwise sealed portion of housing 26. FIG. 12 shows an example auxiliary inlet 310, according to some embodiments. Auxiliary inlet 310 is sealable and unsealable. For example, in some embodiments, auxiliary inlet 310 can be opened to receive air from an environment external to housing 26 thereby unsealing housing 26 and can be closed to seal housing 26 from the external environment. Opening and closing of auxiliary inlet 310 can be actuated based on a temperature detected inside housing 26 (or at a component such as a display 300 or heatsink plate 10) reaching a threshold temperature or range. For example, auxiliary inlet 310 can be opened when a critical temperature is reached and this can allow housing 26 to be cooled more rapidly. In some embodiments, housing 26 includes an auxiliary fan 330 (or other air or fluid moving device) that, when operating, pulls air (or other fluid) from an environment external to housing 26 through auxiliary inlet 310. Optionally, an air filter(s) 320 can be included through which the air (or other fluid) passes through before reaching other components internal to housing 26. The direction of the flow of air is denoted by arrows in FIG. 12. Other configurations of components are possible to direct the flow of air for cooling as desired, according to some embodiments. This can provide an emergency cooling measure that converts the sealed housing 26 to an unsealed housing 26. In some embodiments, an auxiliary exhaust 340 is included in housing to release the air (or other fluid) that was received through auxiliary inlet 310 and can be positioned in housing 26 at a location such that the air (or other fluid) moves through housing 26 before being directed to exit housing 26 through auxiliary exhaust 340.

In some embodiments, the total operating time of each of these components (e.g., fan 330, opened auxiliary inlet 310) can be measured and recorded (e.g., in a data storage or non-transitory memory) and used to configure or optimize the future actuation of these components to provide a desired level of cooling effect (e.g., as measured by reaching a detected temperature or maintaining a detected temperature for a period of time). The recorded data can be used to estimate a filter replacement schedule, in some embodiments.

In some embodiments, an emergency cooling system for the housing 26 is configured to maintain component temperatures based on digital system measurements of several status indicators. These indicators may include but are not limited to the solar load as measured by photocell, display output brightness setting, display power consumption, ambient temperature, internal cabinet temperatures or any other factors affecting thermal management.

In some embodiments, housing 26 is operable in an emergency cooling mode. In this mode, external ambient air is introduced into the housing 26 core through an air filter(s) 320, thereby transitioning the housing 26 from a sealed to an unsealed configuration.

The intake of external air is facilitated by the placement of an auxiliary intake 310 (e.g., air intake) and an auxiliary fan 330, which are arranged to ensure a diagonal cross-flow of external air through the core, helping optimize the cooling efficiency. To reduce the accumulation of dust and debris inside the core, an air filter(s) 320 is positioned at the (e.g., auxiliary intake 310 (e.g., air intake).

In some embodiments, the system further includes a mechanism to log the total operating time of the fan 330, enabling an estimation of the air filter's lifespan for maintenance purposes.

### Frame for Heat Unit

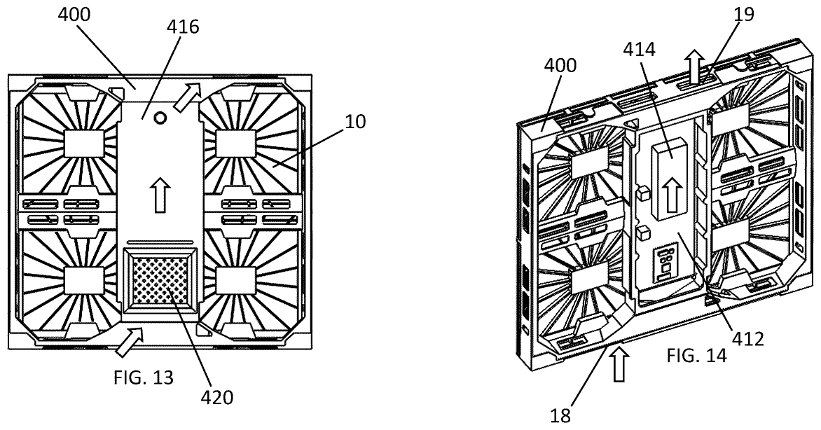

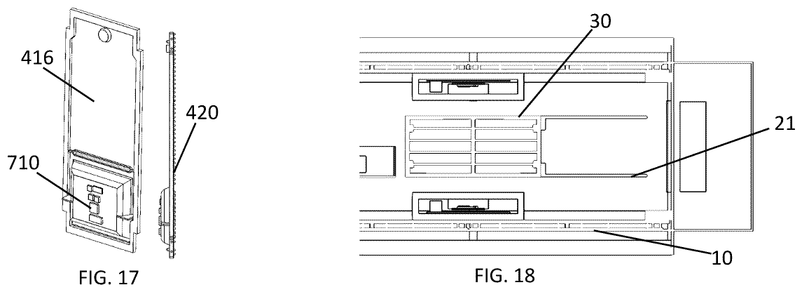

In some embodiments, at least one display unit 260 is arranged in a frame 400 forming a heat unit (FIG. 13). FIG. 13 shows an example heat unit having four display unit 260, according to some embodiments. In the embodiment shown, each heat unit includes at least one heatsink plate 10 and a frame 400. Frame 400 can be a die casted chassis, for example. Frame 400 includes a control board 412 and power supply 414, each of which can be housed inside frame 400 (such as in a subhousing 416) in some embodiments. As examples, the control board 412 can be configured to control at least one display unit 260 and/or display 300. Separately, a control system (e.g., can be remote) can configure a connection between at least one heatsink plate 10 and at least one projection 210 (e.g., by actuating opening or closing of a door that connects heatsink plate 10 to projection 210 when closed), measurement and recordation of temperature, actuation of one or more fans or other air (or fluid) moving devices, and/or actuation of opening or closing inlets, outlets, or exhausts. In some embodiments, subhousing 416 includes a recess or step down feature in an interior surface (e.g., a lid of subhousing 416, such as shown in FIG. 17) that provides thermal contact with one or more internal components such as control board 412 and/or power supply 414. In some embodiments, the interior surface includes a gap or slot configured to be positioned between control board 412 and power supply 414 in subhousing 416 when the interior surface is placed over control board 412 and power supply 414 to form an enclosed subhousing 416. This separation can help decouple these components and instead facilitate heat transfer from power supply 414 to the lid of subhousing 416. The interior surface can include projections to facilitate transfer of heat from control board 412 and/or power supply 414 to the lid or other surface of subhousing 416, in some embodiments. In some embodiments, a lid of subhousing 416 is closeable over subhousing 416 containing control board 412 and power supply 414, and the lid also act as a heat sink for the power supply 414 and control board 412. The lid can have physical contact with the heat generating components in control board 412 and power supply 414 and the lid has heat sink pins on the external side (see 420 in FIG. 13).

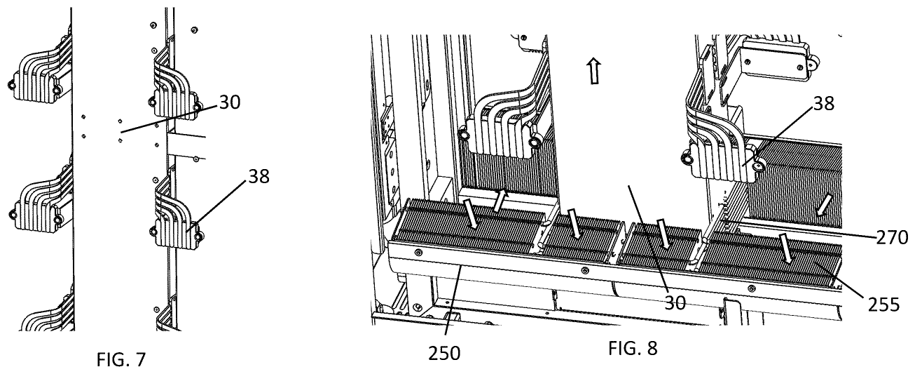

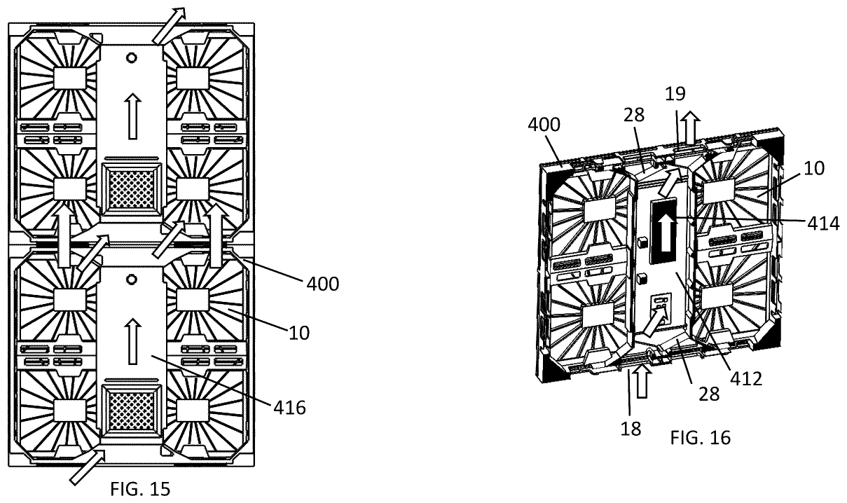

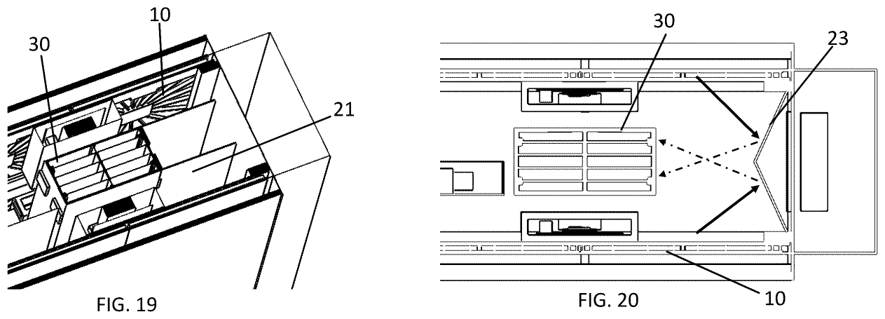

In some embodiments, frame 400 includes a heat sink 420. In some embodiments, the heat sink comprises projections extending outward from frame 400. For example, the heat sink can be a collection of pins as shown in FIG. 13. In some embodiments, such as shown in FIG. 15, frame 400 extends along an outside perimeter of a collection of at least one heatsink plate 10 and at the boundaries between each heatsink plate 10 in the collection. A control board and power supply can be included or housed in a centre of frame 400, an external of which can be populated with pins for facilitation of heat transfer away from the control board and power supply. In some embodiments, multiple frame 400 can be combined to form a door which will be the structure for the individual display units 260 thereby forming the display face 300. The door comprising more than one frame 400 fitted over at least one heatsink plates 10 is openable and closable such as by pivoting away from a plane defined by housing 26. Each door is closeable to connect the heatsink plate(s) 10 to a channel member 30 and openable to disconnect the heatsink plate(s) 10 from the channel member 30, such as by the connection shown in FIG. 3, exemplified by the heat pipe assembly 34. Channel member 30 can be positioned between opposing surfaces each defined by a set of heat units, each surface of heat units for a LED display face 300. Radiative heat transfer can also occur from heatsink plate(s) 10 to channel member 30 where portions thereof are proximate to each other rather than physically connected. Accordingly, the door providing a physical connection (as shown in FIGS. 7 and 8) as well as the radiative heat transfer providing a non-physical connection (as shown in FIGS. 19 and 20) can each provide a thermal connection between the heatsink plate(s) 10 and channel member 30, in some embodiments.

In some embodiments, frame 400 provides radiative heat transfer from heat unit to a channel member 30. For example, the frame 400 can facilitate radiative heat transfer from the heatsink plate 10 of the display unit 400 by facilitating direct line of sight radiation contact. In some embodiments, radiative heat transfer from a subhousing 416 in which control board 412 and power supply 414 are housed is provided to channel member 30 without contact and simply by being positioned proximate to permit radiation heat transfer. Pins (or other projections) on an inner surface of subhousing 416 can be included to connect a surface (e.g., lid) of subhousing 416 to control board 412 (e.g., computer chip) to help directly transfer heat from the control board 412 to lid of subhousing 416. The lid of subhousing 416 is configured to transfer some part of the absorbed heat to channel member 30 and some to the housing 26. FIG. 17 shows an example lid or surface attachable over subhousing 416 for providing an enclosed subhousing 416. In some embodiments, subhousing 416 includes projections 710 from its inner surface. These projections 710 can help extract and transfer heat from control board 412 (e.g., a computer chip) in subhousing 416.

In some embodiments, frame 400 is openable and closeable over heat unit 400. In some embodiments, frame 400 is a modular structure which holds four display units 260 (LED modules). By connecting multiple frames 400 such as shown in FIG. 16, a door structure can be formed. To this door structure, multiple display units 260 are mounted forming a display face 300 (or a portion of display 300). The display unit door can be swing open for servicing. In some embodiments, frame 400 is rotatable over heat unit 400 to support different display size configurations. Any number of frames 400 can be combined to support different display size configurations. The frames 400 can be rotated to achieve the desired display size because the display unit 260 (or LED module) is rectangular shaped (not a perfect square). In some embodiments, frame 400 is a diecast with heatsink pins at a surface and frame 400 provides for horizontal and vertical configurations over heat unit.

### Air Flow Through Subhousing

FIGS. 13, 14, 15, and 16 each show example air flow through a subhousing 416 of frame 400, which can help provide cooling to power supply 414 and/or control board(s) 412 housed inside subhousing 416, in some embodiments. The arrows denote the direction of the flow of air. FIG. 15 shows the flow of air between adjacent frames 400 from a cooler air stream moving over a left set of heat plates to the subhousing of the adjacent frame 400 and exhausted out to the right.

In some embodiments, further leveraging the internal circulatory airflow is a subcabinet (e.g., subhousing 416) associated with one or more frames 400 that comprises a structural housing of die cast aluminum or other fabricated metals, power supply 414, control board 412 (e.g., PCBAs) and electrical connectors. The subhousing 416 housing power supply 414 and control board(s) 412 (e.g., PCBAs) also incorporates exterior facing heatsink features in its lid and an internal cavity for airflow to the components, in some embodiments. One particular challenge is that the compartments of adjacent subhousing 416 are aligned vertically and hot exhaust from one subhousing 416 can be pulled into the intake 18 of the next subhousing 416, reducing the cooling effectiveness. In some embodiments, a selectable diverter baffles (e.g., 28 in FIG. 16) or other devices are used at the bottom intake 18 and top exhaust 19 areas to force air to enter from one side, for example the left, and exit from the opposite side, for example, the right. The selectable diverter baffle comprises a small slat 28 that can be manually placed in left or right position. This example configuration of air intake 18 from left and exhaust 19 on right allows all intake to happen from a cold channel outside the intakes, and all exhaust to vent into a hot channel that is not used to supply any intakes. This addresses the mixing challenge and allows each subhousing 416 be effectively cooled by the coolest air available in the recirculating airflow. “Hot channel” and “cold channel” are used to denote exhaust and intake streams of air, respectively. The air in the hot channel is mixed with the air in housing 26 (e.g., as circulated up behind heat plates of display 300 and down a front surface of display 300) which can be eventually cooled by the heat collector 250.

FIG. 16 shows an example frame 400 which can be fitted over a heat unit, according to some embodiments. In some embodiments, subhousing 416 of frame 400 forms an enclosed housing including air (or other fluid) flow therethrough. In the example shown, directions of flow of air is denoted by the solid arrows in FIG. 15. In some embodiments, diagonal air duct channels at subhousing 416 are provided to allow cold air stream and hot air stream separation outside of subhousing 416. An internal toggle flap or slat 28 or other diversion mechanism can be included to direct air (or other fluid) flow entering subhousing 416 at 18 and exiting subhousing 416 at 19. Air (or other fluid) flow through subhousing 416 can help cool control board 412 and power supply 414 inside subhousing 416, according to some embodiments. Air (or other fluid) from a first stream (e.g., cold stream) moving over a portion of heat unit (e.g., over the surface of vertically aligned heatsink plates 10 of heat unit) is received into subhousing 416 such as at a first corner 18 (e.g., bottom corner), moved through subhousing 416 (e.g., to help provide a cooling effect), and moved out of subhousing 416 at second corner 19 (e.g., top corner). The second corner can be diagonal to the first corner. This air that is moved out of subhousing 416 can join a second stream (e.g., hot stream) of air (or other fluid). In some embodiments, this directionality of air flow can allow air to be collected from a cold stream for cooling inside subhousing 416 and exhausted into a hot stream of air after moving through subhousing 416. In some embodiments, a stream of air that is used as an intake source for subhousing 416 is separated from a stream of air into which air from subhousing 416 is outputted into. The intake stream of air can be cooler than the stream of air that receives the output air from subhousing 416. This can help provide a more efficient cooling mechanism and can help reduce hot air that has been used to help cool a subhousing 416 of a heat unit from being an intake stream into a subhousing 416 of a neighbouring heat unit. For example, in the embodiment shown in FIG. 16, the left upwards arrow denotes a colder stream of air, while the right upwards arrow denotes a hotter stream of air (relative to each other). Each of these streams of air can form part of the air flow circulating in housing 26 upwards over heatsink plates 10 and downwards over a display 300, according to some embodiments. In some embodiments, the pattern of air movement over heatsink plates 10 of adjacent heat units from one side of housing to the other side of housing can be a cold stream, hot stream, plenum, cold stream, hot stream, plenum, cold stream, hot stream. Other patterns of hot and cold streams can be used in other embodiments. References to the “hot stream” means hotter than the “cold stream”, and references to “cold stream” means cooler than the “hot stream”.

### Reflective Layer(s)

In some embodiments, housing 26 includes at least one infrared reflective layer on the protective glass in front of the display 300. For example, outer wall of housing 26 can be comprised of a transparent glass positioned in front of a display 300. The infrared reflective layer(s) can help reject incoming solar heat from entering housing 26, according to some embodiments. Attributes of the infrared reflective layer(s), including positioning within or at or relative to the outer wall, can be configured according to a desired threshold level of reduction of heat entering housing 26 from the external environment, for example.

### Surface Features of Components

In some embodiments, at least one portion of a component of housing 26 is configured with a selected colour, surface roughness, and/or emissivity. A combination can be selected based on a desired capability level of absorption and/or emission of heat. For example, components of heat units can be painted black or with suitable high emissivity coatings. Outer surfaces of channel member 30 can be painted black, or coated with high emissivity coatings for example. Selection of a black colour or suitable coatings can allow heat radiation to be absorbed or emitted with higher efficiency in some embodiments. For example, heat units can be configured for a threshold level of heat emission and channel members 10 can be configured for a threshold level of heat absorption. This can facilitate transfer of heat from heat units to channel members 30, which, in turn, can exhaust heated air to outside housing 26. For example, in some embodiments, this can allow radiation heat transfer to remove or reduce internal heat.

### Additional Features

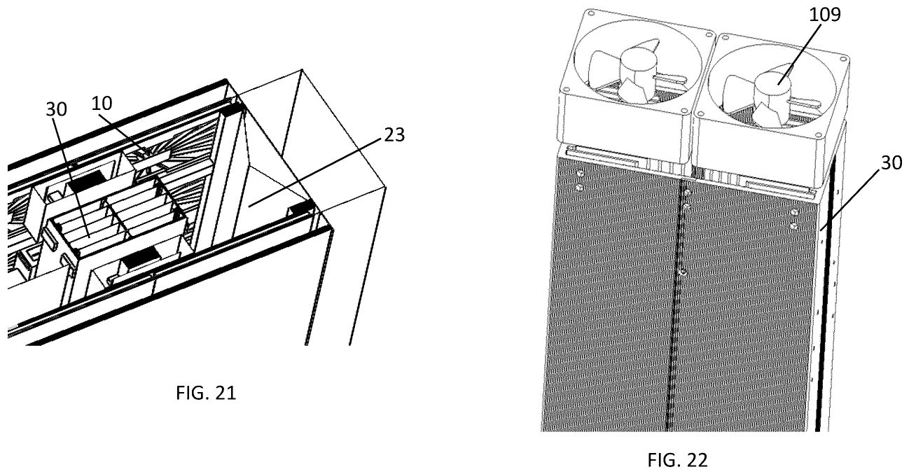

In some embodiments, display units 260 at higher temperatures especially when heated by solar load will radiate heat based on the temperature and the emissivity of the associated heatsink plate 10 in accordance to blackbody radiation. In some embodiments, radiative heat transfer from the high temperature, high emissivity heat sink plate 10 to the low temperature channel member(s) 30 is provided. In some embodiments, the heatsink plates 10 from multiple heat units is a full continuous area radiating heat as infrared radiation, such that many of the rays will not reach the channel member 30 surface to be captured or absorbed, instead escaping and reflecting off different surfaces and being absorbed by the high emissivity heat sink plate 10 and display units 260 on the opposite face without removing the heat from the overall system. In some embodiments, there are provided two different methods for increasing the capture rate of the radiated rays by the channel members 30. One example is to incorporate a flange or other device 21 (see e.g., FIGS. 18 and 19) to enlarge the capture surface of the channel members 30 by thermally bonded attachment. These channel members 30 are arranged in parallel to the heatsink plate 10 of display 300 and are in close proximity. The second method is to incorporate radiative ray reflector surfaces 23 (FIGS. 20 and 21) along the outside edges to reflect escaped rays directly into the channel member 30 for capture and absorption. These methods can be used in the alterative or together or together with other methods.

### Example Experiments

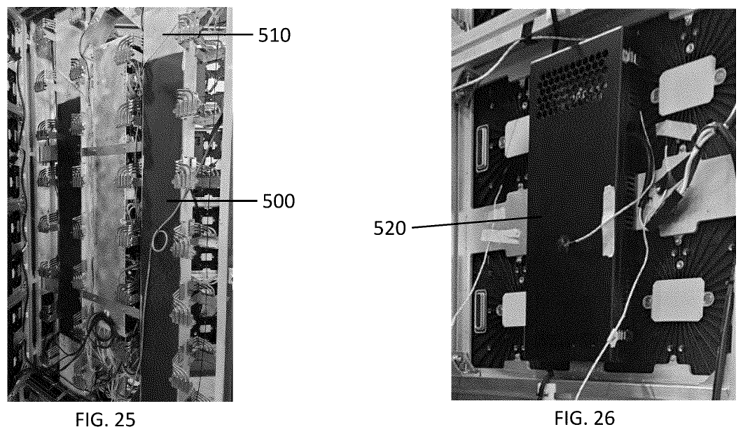

Experiments were performed to illustrate radiative cooling, according to some embodiments. In the experiments, a housing 26 having LED displays 300 were configured as suitable for a transit shelter. FIGS. 25 and 26 show an example housing 26 used in the experiments. At 500, a portion of a channel member 30 was painted with a black matte finish paint. A different portion of channel member 3030 was left unpainted at 510. Displays 300 were powered at a maximum power with all LEDs white at a maximum brightness. The temperature of a component (a heat source) 520 facing the channel member 30 was measured before and after the painting. Temperature was also measured from other locations in and at housing 26.

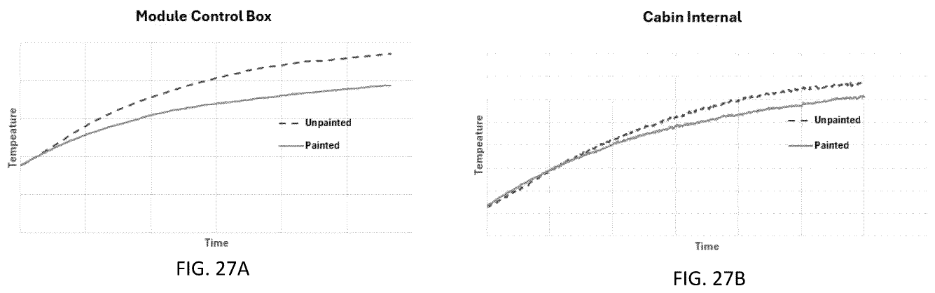

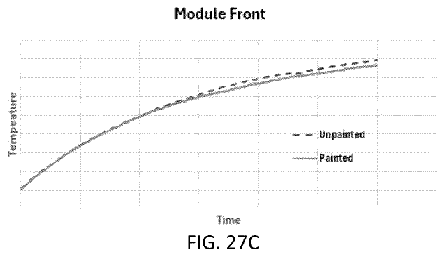

FIGS. 27A, 27B, and 27C show test results of the experiments conducted at room temperature. The dashed line in each graph denotes the results when the channel member 30 was unpainted, while the solid line in each graph denotes the results when the channel member 30 was painted, the temperature measured at the heat source 520 in FIG. 27A, the measured internal air temperature air temperature inside housing 26 shown in FIG. 27B, and the display unit 260 (LED module) temperature shown in FIG. 27C. Considerable temperature reduction was observed after painting even in room temperature. Since radiation is more significant at higher temperatures, it is expected that the radiation coupling can significantly reduce component temperatures under real world outdoor conditions.

In some embodiments, radiation reflectors 23 such as mirrors or polished metallic surfaces with high reflectivity are included in housing 26 and configured to reflect infrared radiation from a heat source (e.g., heatsink plate 10) to a heat sink (e.g., channel member 30). Radiation reflector(s) 23 (FIGS. 20 and 21) can be positioned and angled to direct radiation from a heat source to a heat sink that are not in a line of sight relative to each other (e.g., no unobstructed direct line between the same).

In some embodiments, these methods can implement a radiative heat collector, redirection of radiation (e.g., using radiation reflectors), and/or enhanced receiving areas (e.g., through paint or texture configurations).

In some embodiments, a heat collector is an extended surface thermally bonded to channel member 30 which will absorb the radiation from heat sink plate 10 (see e.g., FIGS. 18 and 19). In some embodiments, a radiation reflector is a component that reflects the IR radiation from the heat sink plate 10 to the channel member 30 and can allow a radiation collector to be omitted, as a radiation collector may be less space efficient (see e.g., FIGS. 20 and 21).

### Additional Examples

In some embodiments, there is provided a housing that includes LED display components positioned therein that are protected from environmental effects, can be utilized in a continuous manner, and dissipates the heat generated therefrom by a configuration that integrates a LED component with a heatsink plate having a skeleton (e.g., formed by ribs or other components) that when bonded to a printed circuit board assembly can dissipate heat through one or more channel members, and said skeleton further being configured to draw heat from the LED component to a centralized heatsink plate component formed by the skeleton of the heatsink plate and from said centralized component into a channel member. Heat doors can be used to draw heat from the centralized component into a channel member. The channel member is formed to allow air travelling through the channel member to be expelled such heat to outside of the housing and thereby cause heat dissipation according to some embodiments.

In some embodiments, there is provided an enclosed LED display comprising: a cabinet wherein the following elements are positioned: an array of LED modules each comprising one or more LED diodes operable to display text and graphics, a printed circuit board assembly (PCBA), and a heatsink plate incorporating ribs and mesas wherein the LED diodes are mounted to the PCBA which is then thermally bonded to the heatsink plate via thermal interface material; structural plenum tubes positioned to draw heat generated by the operation of the LED display through the plenum tube exterior and expel the heat through airflow in the plenum tube interior.

In some embodiments, there is provided an enclosed LED display that further comprises one or more LED display doors: being attached thermally to one or more of the one or more plenum tubes by one or more thermal interconnect brackets which are in contact with the one or more plenum tubes when said LED display door is in a closed position; and being positioned proximate to one of the one or more module heatsinks whereby heat is drawn from the module heatsink into the one or more thermal interconnect brackets and into the one or more plenum tubes; and with radiant heat coupling from LED display door to plenum tubes including heat reflectors positioned in a way to capture and reflect radiant heat rays into the plenum for heat removal from the system.

In some embodiments, there is provided an enclosed LED display that further comprises protective exterior glass covering incorporating infra-red (IR) reflecting or insulating coating or film; one or more fan assemblies directing curtains of air in the space between the front of the LED display door and the interior face of the protective glass; one or more heat collector arrays bonded to the plenum tubes where heat air from the LED display face is collected and transferred to the plenum tubes for removal; one or more LED subcabinet assemblies as part of LED display doors which direct the recirculated air in a path to cool the other electronic components.

In some embodiments, there is provided an enclosed LED display that further comprises cooling system stages based on one or several real-time status measurements; an ambient air fan and filter arrangement that operates at the highest cooling stage (emergency conditions) to draw in cooler ambient air but at the cost of causing buildup on the filter.

Particular embodiments will now be described.

In some embodiments, the cooling system helps ensure that the internal temperature of a LED display unit remains within safe limits, thereby preventing thermal damage to the components, reducing the likelihood of thermal runaway, and ultimately extending the operational lifespan of the unit.

Methods to restrict solar heat gain by using solar blockers, reflective coatings and films, or low emissivity surface coatings are often impractical for use in outdoor LED units, particularly due to their impact on visibility, aesthetics, and the optical properties of the display. A more effective and practical solution involves the use of infrared blocking films on the glass covering of the unit, as the IR portion of the solar spectrum accounts for approximately 50% of the total solar heat gain. The remaining contribution from the visible spectrum, while still significant, is harder to mitigate without adversely affecting the functionality of the LED display.

### Stage 2 Cooling Mode

In some embodiments, a stage 2 cooling system is disclosed for a housing for extracting heat from components within a sealed display core that cannot be coupled conductively to a plenum. The system facilitates the transfer of heat from these components to the internal air within the display core. The heated air is subsequently extracted by an internal heat exchanger, which is thermally coupled to the plenum through heat pipes.

To enhance internal convective heat transfer, a fan assembly is employed to circulate air from the top to the bottom through the cavity between the front of the module and the front glass of the display. The circulating air is directed towards a heat exchanger located at the bottom of the cavity. The heat exchanger extracts thermal energy from the air, transferring the heat to the plenum via the heat pipes. The fan assembly includes two scroll fans, each positioned at the top of the display faces, and configured to push air from the top to the bottom of the display core.

In an alternative embodiment, an additional set of axial fans is incorporated to supplement the scroll fans, enabling the system to overcome pressure losses and thereby increase the overall internal airflow volume.

These axial fans are positioned at the bottom of the display core, where they collect the air that has passed through the heat exchanger and boost it towards the top scroll fans, directing the air through the rear face of the module. The second set of axial fans also functions to provide forced airflow to internal non-module components within the display core.

### Stage 3 Cooling Mode

In some embodiments, an emergency cooling system for a display core is disclosed, configured to maintain component temperatures when ambient temperatures exceed the normal operating range. In this mode, external ambient air is introduced into the display core through an air filter, thereby transitioning the system from a sealed to an unsealed configuration.

The intake of external air is facilitated by the placement of an air intake and an auxiliary fan, which are arranged to ensure a diagonal cross-flow of external air through the core, optimizing the cooling efficiency. To prevent the accumulation of dust and debris inside the core, an air filter is positioned at the air intake.

The system further includes a mechanism to log the total operating time of the fan, thereby enabling an estimation of the air filter's lifespan for maintenance purposes.

In some embodiments, a control system is configured to control switching between cooling mode two and cooling mode three. In some embodiments, both modes are operable simultaneously.

### Additional Cooling Solutions—Die-Cast Modular Module Chassis

In some embodiments, an enhanced cooling method is provided through a die-cast modular chassis for an LED module. The chassis is designed to support and secure up to four individual modules and simultaneously function as a structural component of the LED display's door unit. This modular chassis is rotatable, allowing for flexibility in accommodating various display size configurations, thereby offering adaptability for different installation requirements.

The chassis incorporates an internal cabinet within the die-cast structure, which houses critical components such as the module control board and power supplies. These components are known to generate significant heat during operation and therefore require efficient thermal management. The design of the chassis addresses this by integrating specialized internal airflow channels.

The internal airflow channels are engineered to direct air from a designated cold channel to a hot channel. This ensures that the coldest available air is continually directed toward the internal components, thereby optimizing the cooling efficiency and preventing the buildup of excess heat.

In addition, the system includes a cabinet lid, which serves a dual purpose: as a protective enclosure for the module control board and as an additional heat dissipation element. The lid is equipped with extrusions designed to provide direct physical contact with the module control board at the chip level, facilitating conductive heat transfer. These extrusions enhance the efficiency of heat conduction from the control board to the lid.

The lid is further equipped with heat sink pins on its external surface. These pins are designed to effectively transfer the thermal energy from the lid to the surrounding environment. This comprehensive design provides a robust and efficient heat transfer mechanism, ensuring that both the module control board and the power supplies are effectively cooled, thereby maintaining optimal operating conditions for the LED display unit.

### Additional Cooling Methods—Radiation Cooling

Thermal energy can be transferred through electromagnetic radiation, specifically in the form of infrared radiation. While the contribution of radiative heat transfer is generally insignificant at room temperature, the present invention proposes a method to significantly enhance the overall heat transfer by utilizing radiation. Unlike conductive and convective heat transfer, radiation allows for immediate transfer of thermal energy between the source and sink, without any time delay.

Radiation is inherently a surface-to-surface phenomenon and requires a line-of-sight arrangement between the source and sink. The temperature difference between the source and sink governs the efficiency of radiative heat transfer. The coldest surface in the system, identified as the plenum, serves as the radiation sink. To increase the surface area available for collecting emitted radiation, the plenum surface is grooved, which also impacts convective heat transfer.

The efficiency of emitting and absorbing radiation depends on the emissivity of the participating surfaces. To improve the emissivity, anodizing is employed as a surface treatment method to increase the surface area and emissivity without increasing the overall size of the component. Both the heat source and the heat sink are anodized to improve their radiative properties.

In an alternative embodiment, radiation collectors are used to gather radiation and transfer thermal energy to the plenum or other heat sinks. These collectors are employed in regions where the source and sink are not in direct line of sight, ensuring effective heat transfer despite misalignment.

Additionally, a radiation reflector may be used to direct the emitted radiation from the source toward the sink. The reflector can be a simple highly reflective curved metallic plate, employed in situations where the use of radiation collectors is impractical due to space constraints or higher conduction thermal resistance between the collector and the heat sink. The reflector serves to redirect radiative energy efficiently without requiring direct line-of-sight between the source and sink.

Embodiments described herein can provide many benefits. As an example, tubes create heat dissipation through the bonding of elements, and therefore do not require the incorporation of additional elements that prior art LED displays rely upon, and may not even incorporate such additional elements, within the cabinets for the purpose of heat dissipation. In some embodiments, fans drawing cooling air, heat absorbing posts, etc. are not included. In some embodiments, a heat plate serves as an exterior wall which can also achieve heat dissipation.

In some embodiments, there is provided an outdoor street-level or urban LED display that is enclosed in a protective cabinet, cooled without routine air filter changes, and configured to incorporate: 1) an array of LED modules each with an assembly of LEDs, PCBA and specially bonded heatsink plate components; 2) structural plenum tubes vertically oriented which uses fans to pass external air through its core and permits LED display heat to be dumped into it as a heat remover or heat exchanger; 3) thermal interconnect brackets that conductively transfer LED module heat into the plenum tubes; 4) interior air recirculation with fans for LED display face air curtain and heat collector assembly to gather and transfer heat into the plenum tubes; 5) modular display subcabinet frames that route recirculating air to cool internal electronic components; 6) radiative heat transfer coupling between LED module and electronics into the plenum tubes, and 7) auxiliary intake and fan system with air filter that is only active based on emergency conditions as controlled by real-time status monitoring.

In some embodiments, there is provided a housing including one or more of the following elements: 1) plenums with exterior air running through the plenum acting as primary heatsinks or heat exchanger; 2) “sealed” or non-free air design in normal use, with filtered air aux fan in emergency; 3) in module “mesa” style TIM interface on diecast; 4) scroll fans with radiator-style coupling to main plenums; 5) radiator may include fans such as axial fans, scroll fans or other ways to mitigate pressure loss introduced by radiator fins; 6) stage 3 auxiliary fan turning the “sealed” mode into “unsealed” mode and tracking time via software to drive filter change alerts; 7) radiative heat transfer modules and control box to plenums; 8) diecast power supply with heatsink pins for horizontal and vertical configurations; 9) IR reflecting layers in large laminated glass (maybe obvious step in HVAC); 10) diagonal air duct channels allowing cold air stream and hot air stream separation, features an internal toggle flap; and 11) radiative heat collector/re-direction/enhanced receiving area.

It will be appreciated by those skilled in the art that other variations of the embodiments described herein may also be practiced. Other modifications are therefore possible. Headings herein are for organizational purposes only and are not to be used to limit the description, interpretation, or construction of elements or embodiments, including of the descriptions that the headings precede.

We claim:

1. A housing for a display, the housing comprising:
at least one display connected to at least one heatsink plate, each heatsink plate connected to a door, each door closeable to connect the heatsink plate to a channel member of at least one channel member and openable to disconnect the heatsink plate from the channel member;
each channel member defining a channel through housing, the channel sealed from an interior of housing and configured to receive gas from outside the housing and to exhaust gas to outside the housing; and
the housing sealed from an atmosphere outside of the housing.

2. The housing of claim 1, wherein the door comprises at least one elongated member extending from the channel member to a door plate connectible to the heatsink plate.

3. The housing of claim 1, further comprising at least one circulation device configured to circulate gas over a front surface of each display and behind each display.

4. The housing of claim 3, further comprising at least one heat collector device positioned in a path of the circulated gas and connected to at least one channel member.

5. The housing of claim 1, further comprising at least one auxiliary inlet openable to unseal the housing from the atmosphere outside of the housing.

6. The housing of claim 5, further comprising at least one processor configured to track a duration of time that the at least one auxiliary inlet opened and configured to generate an alert or data record based on the duration.

7. The housing of claim 1, further comprising a frame fittable over at least one or more of the heatsink plate, the frame connectible to at least one other frame to form the door.

8. The housing of claim 7, the frame comprising at least one subhousing housing a control board and a power source for the display.

9. The housing of claim 7, the frame comprising at least one subhousing through which gas is received at a first corner from inside the housing and through which the gas is outputted at a second corner, the second corner diagonal from the first corner.

10. The housing of claim 8, the frame comprising at least one subhousing comprising a set of pins or fins on an exterior surface of a metal cover, the inside of the metal cover contacting the control board through thermal interface material.

11. The housing of claim 1, further comprising at least one infrared reflective layer in a glass extending over a front of at least one of the at least one display.

12. The housing of claim 1, wherein at least one channel member comprises a surface treated, coated, painted, textured, or any combination thereof for heat transfer.

13. The housing of claim 1, wherein at least one heatsink plate comprises a surface treated, coated, painted, textured, or any combination thereof for heat transfer.

14. The housing of claim 1, wherein each heatsink plate is bonded to a printed circuit board with a thermal interface material positioned therebetween.

15. A method for cooling a display in a housing, the method comprising:
circulating gas over a front surface of the display and then over a back surface of the display;
thermally connecting the display, a component connected thereto, or both to a surface of at least one sealed channel through the housing; and
moving external gas through the at least one sealed channel.

16. The method of claim 15, further comprising receiving gas from outside the housing, moving the gas through the housing, and exhausting the gas to outside the housing.

17. The method of claim 15, further comprising moving the gas in through a first corner of a subhousing in the housing, the subhousing housing a power supply, through the subhousing, and out through a second corner of the subhousing, the second corner diagonal from the first corner.

18. The method of claim 15, further comprising providing radiative cooling to the display by absorbing heat from the display over a treated, coated, painted, textured, or any combination thereof surface of at least one sealed channel, an interior face of a component of housing, or both.

19. The method of claim 15, further comprising reflecting infrared heat from reaching the front surface of the display.

20. The method of claim 15, further comprising providing conductive heat transfer from the display or the component connected thereto to the at least one sealed channel.
